(19) United States
(12) Patent Application Publication
(10) Pub. No.: US 2022/0251708 A1
(43) Pub. Date: Aug. 11, 2022

(54) APPARATUS, METHODS, AND SYSTEMS OF USING HYDROGEN RADICALS FOR THERMAL ANNEALING

(71) Applicant: Applied Materials, Inc., Santa Clara, CA (US)

(72) Inventors: Xinming ZHANG, Santa Clara, CA (US); Zhi LIU, Stanford, CA (US); Abhilash J. MAYUR, Salinas, CA (US); Norman L. TAM, Cupertino, CA (US)

(21) Appl. No.: 17/582,980

(22) Filed: Jan. 24, 2022

Related U.S. Application Data
(60) Provisional application No. 63/146,414, filed on Feb. 5, 2021.

(51) Int. Cl. C23C 16/56; H01L 21/02; B08B 7/00; C23C 16/44

(52) U.S. Cl. CPC C23C 16/56; C23C 16/4405; B08B 7/0035; H01L 21/02057

(57) ABSTRACT

Apparatus, methods, and systems use hydrogen radicals during a thermal annealing of film stacks to reduce or remove contaminants (such as phosphorus) from the film stacks. In one implementation, a method of processing a film stack of a substrate, includes conducting a thermal anneal operation on the film stack while the substrate is directly supported on a pedestal heater. The thermal anneal operation includes reducing one or more of a stress or a bow of the film stack. The method includes conducting a radical treatment operation on the film stack after the thermal anneal operation is conducted. The radical treatment operation includes exposing the film stack to hydrogen radicals, and removing contaminant particles from the film stack.

### CROSS-REFERENCE TO RELATED APPLICATIONS

This application claims benefit of U.S. provisional patent application Ser. No. 63/146,414, filed Feb. 5, 2021, which is herein incorporated by reference in its entirety.

### BACKGROUND

### Field

Aspects of the present disclosure generally relate to apparatus, methods, and systems of using hydrogen radicals during thermal annealing of film stacks to reduce or remove contaminants (such as phosphorus) from the film stacks.

### Description of the Related Art

Contaminants can gather on a chamber and on exposed surfaces of substrates during annealing operations, which can result in contamination of the chamber, the substrates, and downstream chambers. Such contamination can hinder device performance, cause process drift, and require costly and time-consuming maintenance for chambers which results in machine downtime. Without the annealing operations, the substrates can have bow or film stress, which can hinder other processing operations.

Therefore, there is a need for improved apparatus, methods, and systems that facilitate one or more of reduced bow and/or stress, reduced substrate contamination, and/or reduced chamber contamination.

### SUMMARY

Aspects of the present disclosure generally relate to apparatus, methods, and systems of using hydrogen radicals during thermal annealing of film stacks to reduce or remove contaminants (such as phosphorus) from the film stacks. In one aspect, a method includes conducting a thermal anneal operation on a film stack to reduce one or more of a stress or a bow of the film stack, and conducting a radical treatment operation on the film stack that exposes the film stack to hydrogen radicals, and removes contaminant particles from the film stack.

In one implementation, a method of processing a film stack of a substrate includes conducting a thermal anneal operation on the substrate and the film stack while the substrate is directly supported on a pedestal heater. The thermal anneal operation includes reducing one or more of a stress or a bow of the film stack. The method includes conducting a radical treatment operation on the substrate and the film stack after the thermal anneal operation is conducted. The radical treatment operation includes exposing the film stack to hydrogen radicals, and removing contaminant particles from the film stack.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic partial view of a system for thermally annealing substrates, according to one implementation.

FIG. 2A is a schematic partial view of a system for thermally annealing substrates, according to one implementation.

FIG. 2B is a schematic view of the system shown in FIG. 2A in a twin chamber configuration, according to one implementation.

FIG. 2C is an enlarged schematic partial sectional view of the first substrate disposed in the first processing volume and supported on the pedestal heater, as shown in FIG. 2B, according to one implementation.

FIG. 2D is a schematic partial sectional view of the first substrate shown in FIG. 2C after undergoing the first processing operation, according to one implementation.

FIG. 3 is a schematic partial view of a system for processing substrates, according to one implementation.

FIG. 4 is a schematic view of a method of processing a film stack of a substrate, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects of the present disclosure generally relate to apparatus, methods, and systems of using hydrogen radicals during processing, such as thermal annealing, of film stacks to reduce or remove contaminants (such as phosphorus) from the film stacks. In one aspect, a method includes conducting a first process (e.g., thermal anneal) operation on a film stack to reduce one or more of a stress or a bow of the film stack, and conducting a second process (e.g., thermal anneal) operation on the film stack that exposes the film stack to hydrogen radicals, and removes contaminant particles from the film stack.

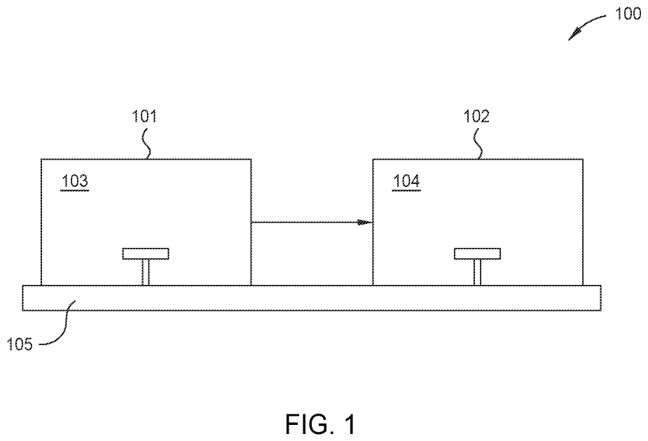

FIG. 1 is a schematic partial view of a system 100 for processing substrates, according to one implementation. The system 100 includes one or more first process chambers (a first process chamber 101 is shown) configured to conduct a thermal anneal operation on a substrate in a first processing volume 103, and one or more second process chambers (a second process chamber 102 is shown) configured to conduct a radical treatment operation on a substrate in a second processing volume 104. The system 100 can be a part of a cluster tool that includes one or more etch chambers, one or more deposition chambers (such as epitaxial deposition chambers, vapor deposition chambers, and/or atomic layer deposition chambers), one or more lithography chambers, and/or one or more oxidation chambers. The one or more first process chambers 101 and the one or more second process chambers 102 are attached to and supported on the same support frame 105. In one embodiment, which can be combined with other embodiments, the one or more first process chambers 101 are one or more thermal anneal chambers, and the one or more second process chambers 102 are one or more radical treatment chambers.

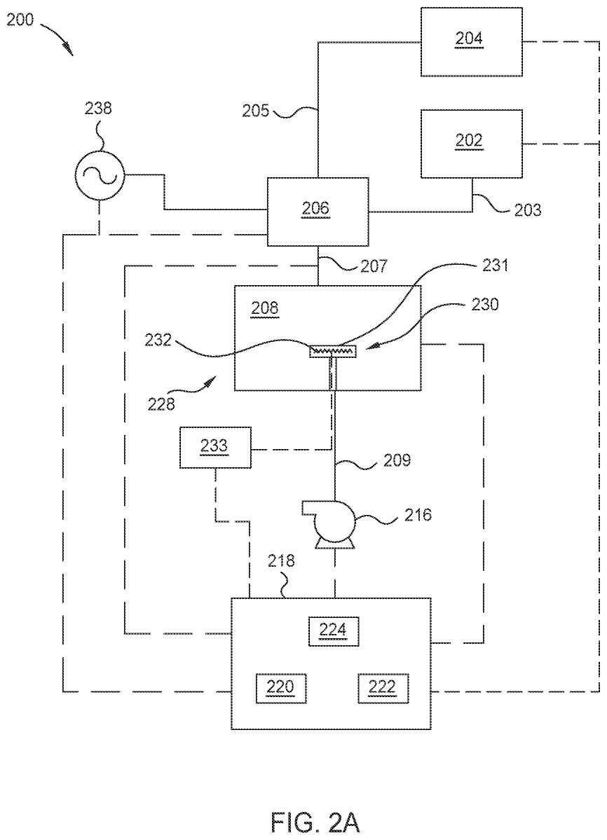

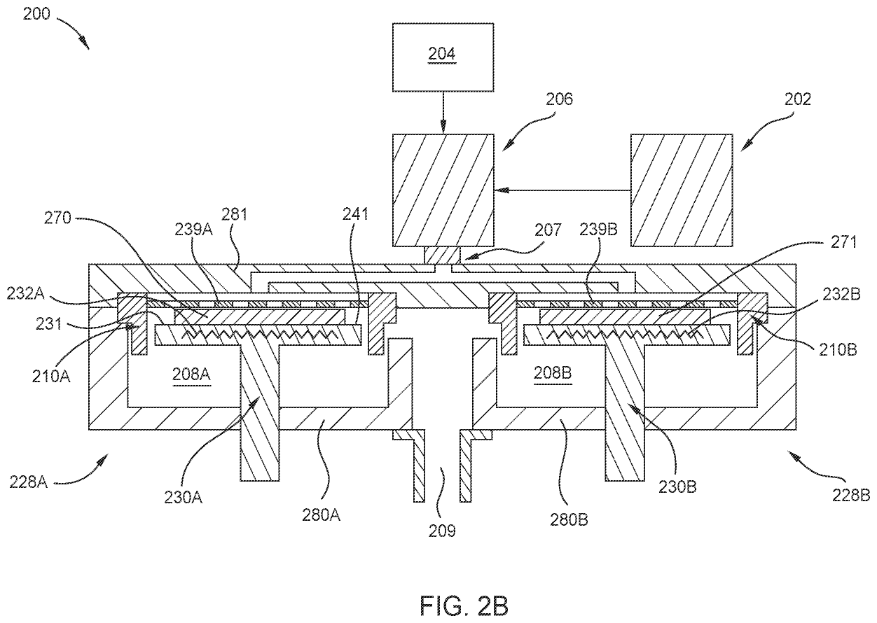

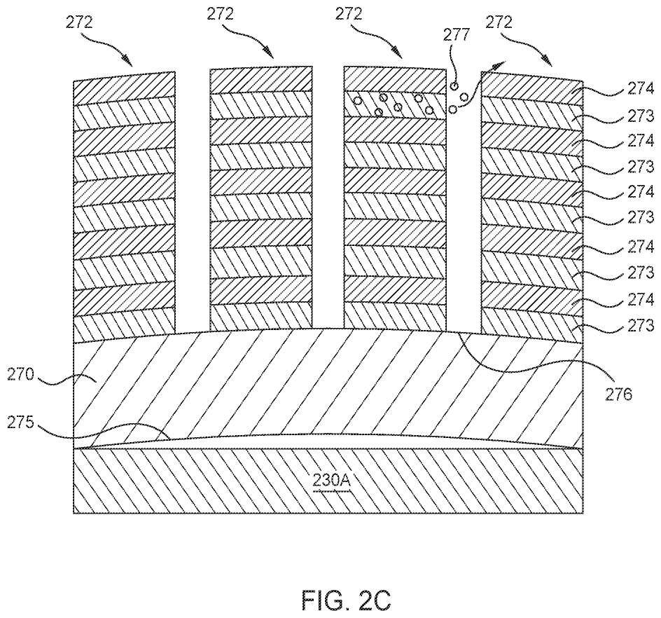

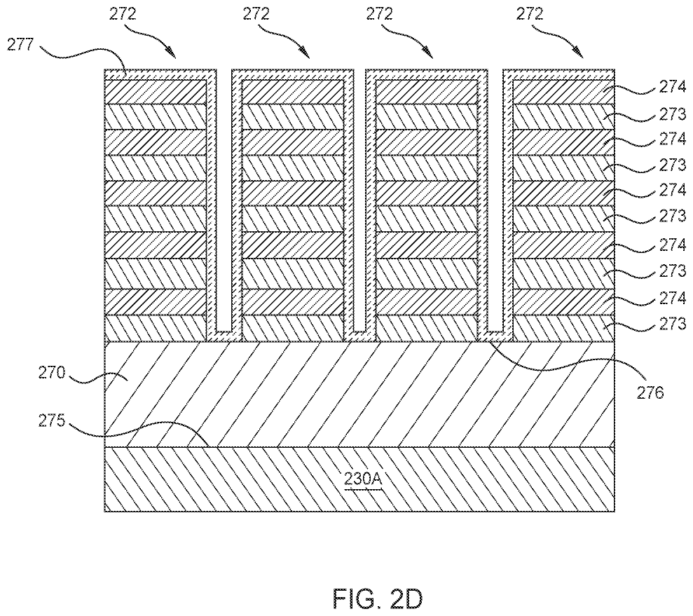

FIG. 2A is a schematic partial view of a system 200 for thermally annealing substrates, according to one implementation. The system 200 includes a first process chamber 228, such as the PYRA® chamber available from Applied Materials, Inc. of Santa Clara, Calif. The system 200 also includes a remote plasma source (RPS) 206, and a gas line 207 coupling the remote plasma source 206 to the first process chamber 228. The present disclosure contemplates that in an in-situ plasma operation may be used in place of the RPS 206. The first process chamber 228 can be used as the first process chamber 101 shown in FIG. 1. The first process chamber 228 can be a heater based process chamber, or a rapid thermal processing (RTP) chamber, such as a rapid thermal anneal (RTA) chamber. The first process chamber 228 can be any thermal processing chamber where delivery of at least one metastable radical molecular species and/or radical atomic species to a processing volume is desired at least for cleaning purposes. The first anneal chamber 228 includes a pedestal heater 230. The pedestal heater 230 includes a base platform that includes a support surface 231. The support surface 231 is circular or rectangular in shape. The pedestal heater 230 includes one or more heater elements 232 embedded in the pedestal heater 230. The one or more heater elements 232 include one or more resistive heater elements, such as wire mesh(es) and/or resistive heating coil(s). The pedestal heater 230 includes a ceramic or aluminum body with the one or more heater elements 232 embedded in the ceramic or aluminum body. The one or more heater elements 232 are connected to a power source 233 that supplies power, such as electrical power (for example direct current or alternating current), to the one or more heater elements 232. The one or more heater elements 232 and the pedestal heater 230 are used to heat and control a temperature of a substrate (disposed on the pedestal heater 230) and a film stack of the substrate.

The RPS 206 is coupled to a power source 238. The power source 238 is used as an excitation source to ignite and maintain a plasma in the RPS 206. In one embodiment, which can be combined with other embodiments, the RPS 206 includes an inductively coupled plasma (ICP) source, a transformer coupled plasma (TCP) source, and/or a capacitively coupled plasma (CCP) source. In one embodiment, which can be combined with other embodiments, the power source 238 is a radio frequency (RF) source. In one example, which can be combined with other examples, the RF source delivers power between about 5 kW to about 9 kW, such as about 7 kW. In one embodiment, which can be combined with other embodiments, the RPS 206 includes one or more microwave resonators.

The RPS 206 is coupled to a first gas source 202 via a first gas conduit 203 and a second gas source 204 via a second gas conduit 205. The first gas source 202 supplies a first gas that includes one or more of hydrogen, oxygen, argon, and/or nitrogen. The flow rate of the first gas into the first processing volume 208 is within a range of about 10 sccm to about 100,000 sccm. In one embodiment, which can be combined with other embodiments, nitrogen is supplied at a flow rate within a range of 10 sccm to 50,000 sccm, oxygen is supplied at a flow rate within a range of 10 sccm to 30,000 sccm, hydrogen is supplied at a flow rate within a range of 10 sccm to 50,000 sccm, and/or argon is supplied at a flow rate within a range of 10 sccm to 50,000 sccm.

The second gas source 204 supplies a second gas, and the second gas includes oxygen gas. Oxygen plasma is formed using the RPS 206 by introducing about 1 sccm to about 50,000 sccm of oxygen gas, such as about 10 sccm to 50,000 sccm of oxygen gas introduced to the first processing volume 208.

A vacuum pump 216 is used to maintain a gas pressure in the first processing volume 208. The vacuum pump 216 evacuates post-processing gases and/or by-products of the process via an exhaust 209.

A controller 218 is coupled to the system 200 to control operations of the first gas source 202, the second gas source 204, the first processing volume 208, the RPS 206, the vacuum pump 216, the gas flow in the gas line 207 to the first process chamber 228, the pedestal heater 230, the one or more heater elements 232, the power source 233, and/or the power source 238. The controller 218 can control upward and downward movement of the pedestal heater 230. The controller 218 includes a central processing unit (CPU) 224, a memory 220 containing instructions, and support circuits 222 for the CPU 224. The controller 218 controls the system 200 directly, or via other computers and/or controllers (not shown) coupled to the first process chamber 228, the first gas source 202, the second gas source 204, the first processing volume 208, the RPS 206, the vacuum pump 216, the gas line 207, the pedestal heater 230, the one or more heater elements 232, the power source 233, and/or the power source 238. The controller 218 is of any form of a general-purpose computer processor that is used in an industrial setting for controlling various chambers and equipment, and sub-processors thereon or therein.

The memory 220, or non-transitory computer readable medium, is one or more of a readily available memory such as random access memory (RAM), read only memory (ROM), floppy disk, hard disk, flash drive, or any other form of digital storage, local or remote. The support circuits 222 are coupled to the CPU 224 for supporting the CPU 224 (a processor). The support circuits 222 include cache, power supplies, clock circuits, input/output circuitry and subsystems, and the like. Substrate processing parameters and operations are stored in the memory 220 as a software routine that is executed or invoked to turn the controller 218 into a specific purpose controller to control the operations of the system 200. The controller 218 is configured to conduct any of the methods described herein. The instructions stored on the memory 220, when executed, cause one or more of the operations 401, 403, 405, and 407 of the method 400 (described below) to be conducted.

The instructions in the memory 220 of the controller 218 can include one or more machine learning/artificial intelligence algorithms that can be executed in addition to the operations described herein. As an example, a machine learning/artificial intelligence algorithm executed by the controller 218 can optimize and alter operational parameters (such as the anneal time, the anneal pressure, the anneal temperature, the radical time, the radical pressure, the radical temperature, the clean time, the clean temperature, and/or the clean pressure—each described below) based on one or more sensor measurements taken by one or more sensors. The one or more sensors are configured to measure (as the one or more sensor measurements) one or more of: a temperature in the one or more first process chambers, a pressure in the one or more first process chambers, a temperature in the one or more second process chambers, a pressure in the one or more second process chambers, a contaminant amount (such as phosphorus amount) on the substrate and/or the film stack, and/or a contaminant amount (such as phosphorus amount) on inner surfaces of the one or more first process chambers. The one or more sensors may be disposed in or coupled to the one or more first process chambers and/or the one or more second process chambers. In one embodiment, which can be combined with other embodiments, the machine learning/artificial intelligence algorithm executed by the controller 218 determines an optimal temperature, an optimal time, an optimal pressure, an optimal gas composition, and/or an optimal gas injection flow rate for use in the thermal anneal operation, the radical treatment operation, and/or the cleaning of the one or more first process chambers.

FIG. 2A shows a first process chamber 228 which can be used in place of the first process chamber 101. Alternatively, the first process chamber 228 can be employed in a twin chamber configuration as shown in FIG. 2B. FIG. 2B is a schematic view of the system 200 shown in FIG. 2A in a twin chamber configuration, according to one implementation. The twin chamber configuration may be used as the one or more first process chambers 101 of the system 100 shown in FIG. 1. The twin chamber configuration includes two respective processing regions 228A, 228B that are in fluid communication with each other. Each processing region 228A, 228B can be configured to include one or more of the components, features, aspects, and/or properties of the first process chamber 228 shown in FIG. 2A.

Each of the processing regions 228A, 228B includes a respective lower chamber body 280A, 280B. The present disclosure contemplates that the processing regions 228A, 228B can share the same lower chamber body. The processing regions 228A, 228B share the same upper chamber body 281. The present disclosure contemplates that the processing regions 228A, 228B can each respectively include a distinct upper chamber body.

Each of the processing regions 228A, 228B includes: respective pedestal heaters 230A, 230B similar to the pedestal heater 230; respective one or more heater elements 232A, 232B similar to the one or more heater elements 232; and/or respective first processing volumes 208A, 208B similar to the first processing volume 208. The processing regions 228A, 228B share a single RPS 206 that provides the first gas (during a thermal anneal operation) and the oxygen plasma (during a later clean operation to clean the processing regions 228A, 228B) to the first processing volumes 208A, 208B. The RPS 206 is coupled to the first gas source 202 and the second gas source 204. Each of the processing regions 228A, 228B includes a respective process kit 210A, 210B. A process kit includes one or more components inside the respective one of the processing regions 228A, 228B used for on-substrate performance, such as liners. The liners can be made from quartz, ceramic, or metal. The processing regions 228A, 228B are coupled to share a single controller 218, or can be coupled to separate controllers 218. The present disclosure contemplates that portions of the process kits 210A, 210B may move and/or include flow openings to allow the first gas and the oxygen plasma to flow to the exhaust 209. The system 200 can include a valve, disposed for example along the exhaust 209, such that the first gas and the oxygen plasma are not exhausted and are instead directed to the first processing volumes 208A, 208B during the thermal anneal operation and the later clean operation. Each of the processing regions 228A, 228B includes respective gas distribution plates 239A, 239B.

A first substrate 270 and a second substrate 271 are directly supported respectively on the pedestal heaters 230A, 230B to undergo a thermal anneal operation.

FIG. 2C is an enlarged schematic partial sectional view of the first substrate 270 disposed in the first processing volume 208A and supported on the pedestal heater 230A, as shown in FIG. 2B, according to one implementation. The first substrate 270 includes a plurality of film stacks 272 formed thereon for memory structures. The first substrate 270 is a silicon substrate. Each of the plurality of film stacks 272 includes a plurality of first layers 273 and a plurality of second layers 274 disposed in an alternating arrangement. Each of the film stacks 272 includes a total number of layers (including the first layers 273 and the second layers 274), and the total number of layers is 56, 128, 256, or higher. The first layers 273 are polysilicon layers and the second layers 274 are oxide layers, such as silicon oxide. A backside surface 275 of the first substrate 270 directly contacts the pedestal heater 230A. One or more outer edges 241 (shown in FIG. 2B) of the support surface 231 of the pedestal heater 230A surround the backside surface 275 of the first substrate 270 such that the support surface 231 has an outer diameter that is larger than an outer diameter of the first substrate 270. The film stacks 272 are formed on a frontside surface 276 of the first substrate 270. As shown in FIG. 2C, the first substrate 270 and the film stacks 272 each include a bow and a stress.

FIG. 2D is a schematic partial sectional view of the first substrate 270 shown in FIG. 2C after undergoing the first processing operation, according to one implementation. During the first processing operation (which is a thermal anneal operation), contaminant particles 277 outgas from the first layers 273 and deposit on exposed surfaces of the first substrate 270 and the film stacks 272. The backside surface 275 of the first substrate 270 being directly supported on the pedestal heater 230A facilitates protecting the backside surface 275 and the support surface 231 from the contaminant particles 277. The backside surface 275 and the support surface 231 are protected such that deposition of the contaminant particles 277 on the backside surface 275 and the support surface 231 is reduced compared to furnace operations where both frontside surfaces and backside surfaces of substrates are completely exposed. During the thermal anneal operation, heat is transferred to the first substrate 270 and the film stacks 272 to reduce the bow and the stress of the first substrate 270 and the film stacks 272.

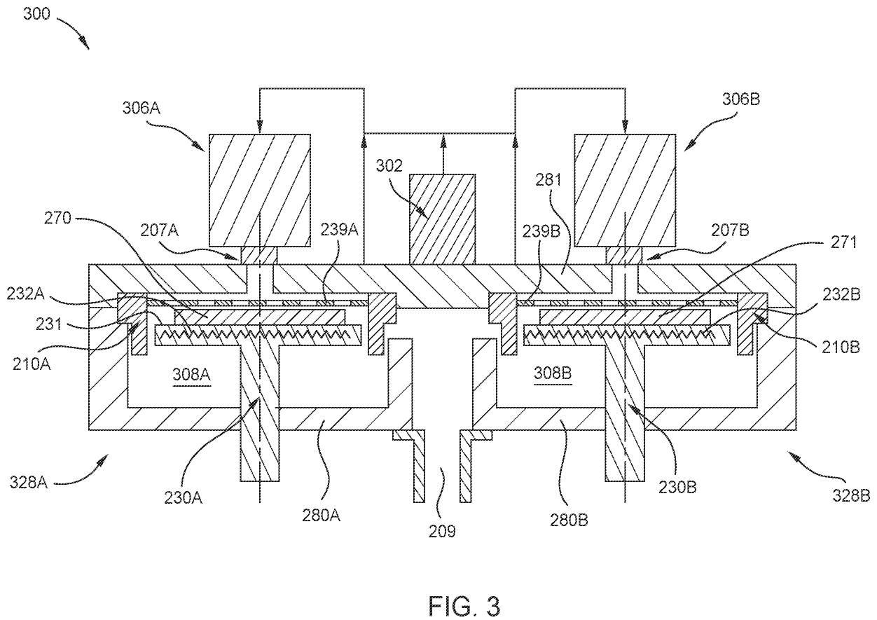

FIG. 3 is a schematic partial view of a system 300 for processing substrates, according to one implementation. The system 300 is similar to the system 200 shown in FIGS. 2A-2D, and includes one or more—but not all—of the aspects, features, components, and/or properties thereof. The system 300 includes a second process chamber having two respective second processing regions 328A, 328B that may be used as the one or more second process chambers 102 shown in FIG. 1. The second processing regions 328A, 328B are similar to the processing regions 228A, 228B, and include one or more—but not all—of the aspects, features, components, and/or properties thereof.

Each of the second processing regions 328A, 328B includes: respective pedestal heaters 230A, 230B similar to the pedestal heater 230; respective remote plasma sources 306A, 306B similar to the RPS 206; respective gas lines 207A, 207B similar to the gas line 207; respective one or more heater elements 232A, 232B similar to the one or more heater elements 232; and/or respective second processing volumes 308A, 308B similar to the first processing volume 208. In one embodiment, which can be combined with other embodiments, the second processing regions 328A, 328B can share a single RPS.

The system 300 includes a first gas source 302 similar to the first gas source 202 described above, and can include one or more of the aspects, features, components, and/or properties thereof. In one embodiment, which can be combined with other embodiments, each respective RPS 206A, 206B is coupled to share a single first gas source 302. In one embodiment, which can be combined with other embodiments, each RPS 206A, 206B can be coupled to a distinct first gas source. The first gas source 302 supplies one or more gases that include hydrogen, oxygen, and/or argon, such as pure hydrogen or a combination of a first gas flow of argon and a second gas flow of hydrogen or oxygen at any flow rate ratio of hydrogen or oxygen to argon, such as a flow rate ratio of hydrogen/oxygen:argon that is within a range of 1:350 to 150:1. In embodiments in which the first gas source 302 supplies pure hydrogen, it is contemplated that the purity of the hydrogen is 95% or greater, such as 96% or greater, 97% or greater, 98% or greater, 99% or greater, 99.5% or greater, or 99.9% or greater. In one embodiment, which can be combined with other embodiments, the first gas flow flows argon at a flow rate within a range of 10 sccm to 3,500 sccm to ignite plasma, and then the second gas flow flows hydrogen or oxygen at a flow rate within a range of 10 sccm to 1,500 sccm to provide hydrogen plasma or oxygen plasma.

Each RPS 206A, 206B generates hydrogen radicals using the gas, and supplies the hydrogen radicals to the respective second processing volumes 308A, 308B and to the first substrate 270 and the second substrate 271 during a radical treatment operation to clean the first and second substrates 270, 271 and reduce or remove the contaminant particles 277 from the film stacks 272 and the first and second substrates 270, 271. The present disclosure contemplates that the second substrate 271 can include film stacks similar to the film stacks 272 of the first substrate 270. The system 300 can include one or more ion filters that filter out ions from the plasma generated using the RPSs 206A, 206B.

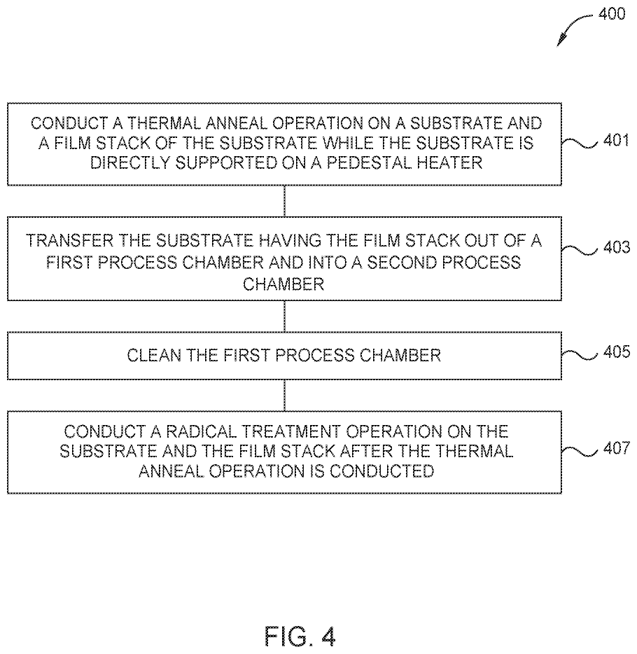

FIG. 4 is a schematic view of a method 400 of processing a film stack of a substrate, according to one implementation. Operation 401 includes conducting a thermal anneal operation on the substrate and the film stack while the substrate is directly supported on a pedestal heater. A backside surface of the substrate is in direct contact with a support surface of the pedestal heater. One or more outer edges of the support surface surround the backside surface of the substrate. The thermal anneal operation includes reducing one or more of a stress or a bow of the film stack and/or the substrate. The thermal anneal operation on the substrate and the film stack is conducted in a first process chamber. The pedestal heater is a heater base platform. The thermal anneal operation includes flowing a first gas composition into the first process chamber, and exposing the film stack and the substrate to the first gas composition. The first gas composition includes one or more of hydrogen, nitrogen, helium, and/or oxygen. In some embodiments, which can be combined with other embodiments, the first gas composition includes pure hydrogen, pure nitrogen, pure helium, pure oxygen, or a gas mixture. In embodiments in which the first gas composition includes a gas mixture, it is contemplated that the gas mixture includes one or more inert gases and a reactive gas, and with a flow rate ratio of inert gas(es):reactive gas of any number, such as a flow rate ratio that is within a range of 1:100 to 100:1. The one or more inert gases include one or more of nitrogen and/or helium, and the reactive gas includes hydrogen or oxygen.

In embodiments in which the first gas composition includes pure hydrogen, it is contemplated that the purity of the hydrogen is 95% or greater, such as 96% or greater, 97% or greater, 98% or greater, 99% or greater, 99.5% or greater, or 99.9% or greater. In embodiments in which the first gas composition includes pure nitrogen, it is contemplated that the purity of the nitrogen is 95% or greater, such as 96% or greater, 97% or greater, 98% or greater, 99% or greater, 99.5% or greater, or 99.9% or greater. In embodiments in which the first gas composition includes pure helium, it is contemplated that the purity of the helium is 95% or greater, such as 96% or greater, 97% or greater, 98% or greater, 99% or greater, 99.5% or greater, or 99.9% or greater. In embodiments in which the first gas composition includes pure oxygen, it is contemplated that the purity of the oxygen is 95% or greater, such as 96% or greater, 97% or greater, 98% or greater, 99% or greater, 99.5% or greater, or 99.9% or greater. In some embodiments, which can be combined with the other embodiments, the flowing the first gas composition includes one or more of: flowing pure helium at a flow rate that is within a range of 10 sccm to 50,000 sccm, flowing pure nitrogen at a flow rate that is within a range of 10 sccm to 50,000 sccm, flowing pure oxygen at a flow rate that is within a range of 10 sccm to 30,000 sccm, and/or flowing pure hydrogen at a flow rate that is within a range of 10 sccm to 50,000 sccm.

The thermal anneal operation lasts for an anneal time that is 10 minutes or greater, such as within a range of 10 minutes to 90 minutes, for example within a range of 10 minutes to 30 minutes. The thermal anneal operation is conducted at an anneal temperature that is within a range of 400 degrees Celsius to 650 degrees Celsius, such as 500 degrees Celsius to 600 degrees Celsius. The thermal anneal operation is conducted at a anneal pressure that is less than 760 Torr, such as within a range of 10 Torr to 530 Torr, for example within a range of 20 Torr to 530 Torr.

Operation 403 includes transferring the substrate with the film stack out of the first process chamber and into a second process chamber. The substrate with the film stack is transferred out of the first process chamber after conducting the thermal anneal operation on the film stack at operation 401.

Operation 405 includes cleaning the first process chamber. The first process chamber is cleaned after the substrate with the film stack is transferred out of the first process chamber at operation 403. The cleaning the first process chamber includes flowing a plasma into a first processing volume of the first process chamber from a remote plasma source, and exposing inner surfaces of the first process chamber to the plasma. The plasma is an oxygen plasma, which reacts with contamination (e.g., phosphorus) in the first process chamber to form volatile species which are exhausted from the first process chamber. The oxygen plasma flows into the first processing volume at a flow rate that is within a range of 10 sccm to 50,000 sccm.

The cleaning of operation 405 lasts for a clean time that is within a range of 10 minutes to 30 minutes. The cleaning of operation 405 is conducted at a clean temperature that is about 600 degrees Celsius, such as from 570 to 630 degrees Celsius. The cleaning of operation 405 is conducted at a clean pressure that is within a range of 10 mTorr to 530 Torr. The cleaning of operation 405 removes contaminant particles (such as phosphorus) from the inner surfaces of the first process chamber. The contaminant particles include particles that have outgassed from layers of the film stack during the thermal anneal operation of operation 401. The contaminant particles are removed from the inner surfaces such that the amount of contaminant particles on the exposed inner surfaces of the first process chamber is lowered below a detection threshold, such as by detection using one or more contaminant sensors. In some embodiments, it is contemplated that operations 401 and 403 can be repeated such that more than one substrate/film stack are successively processed and transferred before conducting operation 405.

Operation 407 includes conducting a radical treatment operation on the substrate and the film stack after the thermal anneal operation is conducted. The radical treatment operation includes exposing substrate and the film stack to hydrogen radicals, and removing contaminant particles, such as phosphorus, from surfaces of the film stack and the substrate. The contaminant particles are removed from exposed outer surfaces of the substrate and the film stack. In one embodiment, which can be combined with other embodiments, the contaminant particles include particles that have outgassed from layers of the film stack during the thermal anneal operation of operation 401. The radical treatment operation is conducted in the second process chamber. In some embodiments, it is contemplated that operation 407 can be conducted after operation 405. In some embodiments, it is contemplated that operation 407 can be conducted at least partially simultaneously with operation 405. In some embodiments, it is contemplated that operation 407 can be conducted before operation 405. The radical treatment operation cleans the contaminant particles from the film stack and/or the substrate.

The radical treatment operation includes flowing radicals of a second gas composition into the second process chamber and exposing the contaminant particles on the film stack and the substrate to the radicals of the second gas composition. The second gas composition includes pure hydrogen or a hydrogen-argon mixture. In embodiments in which the second gas composition includes pure hydrogen, it is contemplated that the purity of the hydrogen is 95% or greater, such as 96% or greater, 97% or greater, 98% or greater, 99% or greater, 99.5% or greater, or 99.9% or greater.

The radical treatment operation lasts for a radical time that is within a range of 30 seconds to 30 minutes, such as within a range of 30 seconds to 90 seconds. The radical treatment operation is conducted at a radical temperature that is within a range of 100 degrees Celsius to 650 degrees Celsius. The radical treatment operation is conducted at a radical pressure that is less than 1 Torr. In one embodiment, which can be combined with other embodiments, the radical treatment operation results in formation of a volatile phosphine in the second process chamber.

Aspects of the method 400 facilitate at least: reduced contamination of chambers, substrates, and film stacks compared to conventional methods; reduced risk of film stack delamination compared to conventional methods; and easily and cost-effectively cleaning chambers. For example, the anneal pressure facilitates sublimation of the contaminant particles (such as phosphorus) to reduce contamination of chambers, substrates, and film stacks. Additionally, the anneal time facilitates a reduced risk of delamination of the film stack from the substrate compared to conventional methods because a bow and/or a stress of the film stack and/or the substrate is reduced. Furthermore, one or more aspects of the cleaning of operation 405 facilitate cleaning the first process chamber in-situ without necessitating the opening of the first process chamber, such as to manually clean the first process chamber. As another example, the radical temperature facilitates more contaminant particles to be removed from the substrate and the film stack during the radical treatment operation compared to conventional methods.

Conventionally, annealing furnaces are utilized for thermal treatments of film stacks, such as those described herein. However, annealing furnaces conventionally utilize substrate boats to hold multiple substrates in a vertical stack. The substrate boats leave both upper and lower surfaces of processed substrates exposed. Thus, as contaminants such as phosphorus outgas from film stacks, the contaminants not only adsorb to surfaces of the film stack, but also adsorb to bottom surfaces of adjacent substrates. Once transferred to downstream processes, such as those which do not utilize substrate boats, the contaminants on the backside of the substrate generally remain as this backside surface is concealed during these processes (as a result of the support structures used to support substrates in downstream processes). Because these backside contaminants are not removed, the contaminants jeopardize substrate quality and/or introduce undesired contamination to downstream process chambers.

Benefits of the present disclosure compared to conventional systems, apparatus, and methods include thermally annealing substrates with backside surfaces shielded from contaminants, thermally annealing substrates at low pressures to facilitate sublimation of contaminants to reduce contamination, reduced chance of film stack delamination, quickly and cost-effectively cleaning annealing chambers, reduced bow and/or stress for film stacks, reduced substrate contamination, reduced chamber contamination, reduced downstream chamber contamination, downstream process efficacy, cost efficiency, time efficiency, increased throughput, and reduced machine downtime.

It is contemplated that one or more aspects disclosed herein may be combined. As an example, one or more aspects, features, components, and/or properties of the system 100, the system 200, the system 300, and the method 400 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A method of processing a film stack of a substrate, comprising:
conducting a thermal anneal operation on the substrate and the film stack while the substrate is directly supported on a pedestal heater, the thermal anneal operation comprising reducing one or more of a stress or a bow of the film stack; and
then conducting a radical treatment operation on the substrate and the film stack, the radical treatment operation comprising:
exposing the film stack to hydrogen radicals; and
removing contaminant particles from the film stack.

2. The method of claim 1, wherein:
the thermal anneal operation on the substrate and the film stack is conducted in a first process chamber; and
the radical treatment operation on the substrate and the film stack is conducted in a second process chamber.

3. The method of claim 2, further comprising:
transferring the substrate out of the first process chamber after the thermal anneal operation on the substrate and the film stack is conducted; and
cleaning the first process chamber, the cleaning of the first process chamber comprising flowing an oxygen plasma into a first processing volume of the first process chamber from a plasma source;
wherein the oxygen plasma flows into the first processing volume at a flow rate that is within a range of 10 sccm to 50,000 sccm, and the cleaning of the first process chamber is conducted at a clean temperature that is about 600 degrees Celsius.

4. The method of claim 3, wherein the cleaning of the first process chamber is conducted prior to conducting the radical treatment operation on the substrate and the film stack.

5. The method of claim 3, wherein the cleaning of the first process chamber is conducted at least partially simultaneously with conducting the radical treatment operation on the substrate and the film stack.

6. The method of claim 3, wherein the cleaning of the first process chamber is conducted after conducting the radical treatment operation on the substrate and the film stack.

7. The method of claim 1, wherein the thermal anneal operation further comprises:
flowing a first gas composition into the first process chamber; and
exposing the film stack and the substrate to the first gas composition.

8. The method of claim 7, wherein the first gas composition includes one or more gases selected from a group consisting of hydrogen, nitrogen, helium, and oxygen.

9. The method of claim 7, wherein the first gas composition includes a mixture of an inert gas and a reactive gas.

10. The method of claim 7, wherein during the thermal anneal operation, a backside surface of the substrate is in direct contact with a support surface of the pedestal heater.

11. The method of claim 10, wherein an outer diameter of the support surface is larger than an outer diameter of the backside surface of the substrate.

12. The method of claim 7, wherein:
the thermal anneal operation lasts for an anneal time of at least 10 minutes;
the thermal anneal operation is conducted at an anneal temperature that is within a range of 400 degrees Celsius to 650 degrees Celsius; and
the thermal anneal operation is conducted at an anneal pressure that is within a range of 10 Torr to 530 Torr.

13. The method of claim 7, wherein the radical treatment operation further comprises:
exposing the film stack to a second gas composition containing the hydrogen radicals, the second gas composition including hydrogen.

14. The method of claim 13, wherein the second gas composition further includes argon.

15. The method of claim 13, wherein:
the radical treatment operation lasts for a radical time that is within a range of 30 seconds to 90 seconds;
the radical treatment operation is conducted at a radical temperature that is within a range of 100 degrees Celsius to 650 degrees Celsius; and
the radical treatment operation is conducted at a radical pressure that is less than 1 Torr.

16. A method of processing a film stack of a substrate, comprising:
conducting a thermal anneal operation on the substrate and the film stack while a backside surface of the substrate is in direct contact with a support surface of a pedestal heater, wherein an outer diameter of the support surface is larger than an outer diameter of the backside surface, the thermal anneal operation comprising:
flowing a first gas composition, the first gas composition comprising one or more of hydrogen, helium, nitrogen, or oxygen; and
exposing the film stack and the substrate to the first gas composition;
wherein the thermal anneal operation lasts for an anneal time that is 10 minutes or greater, the thermal anneal operation is conducted at an anneal temperature that is within a range of 400 degrees Celsius to 650 degrees Celsius, and the thermal anneal operation is conducted at an anneal pressure that is within a range of 10 Torr to 530 Torr; and
then conducting a radical treatment operation on the substrate and the film stack, the radical treatment operation comprising:
flowing a second gas composition including hydrogen radicals; and
exposing the film stack to the hydrogen radicals;
wherein the radical treatment operation lasts for a radical time that is within a range of 30 seconds to 90 seconds, the radical treatment operation is conducted at a radical temperature that is within a range of 100 degrees Celsius to 650 degrees Celsius, and the radical treatment operation is conducted at a radical pressure that is less than 1 Torr.

17. The method of claim 16, wherein:
the thermal anneal operation on the substrate and the film stack is conducted in a first process chamber; and
the radical treatment operation on the substrate and the film stack is conducted in a second process chamber.

18. The method of claim 16, further comprising:
transferring the substrate out of the first process chamber after the thermal anneal operation on the substrate and the film stack is conducted; and
cleaning the first process chamber, the cleaning of the first process chamber comprising flowing an oxygen plasma into a first processing volume of the first process chamber from a plasma source;
wherein the oxygen plasma flows into the first processing volume at a flow rate that is within a range of 10 sccm to 50,000 sccm, and the cleaning of the first process chamber is conducted at a clean temperature that is about 600 degrees Celsius.

19. The method of claim 16, wherein:
the second gas composition comprises pure hydrogen or a mixture of hydrogen of argon.

20. A non-transitory computer readable storage medium having stored thereon, computer-executable instructions that, when executed by a processor, cause the processor to perform a method of processing a film stack of a substrate, the method comprising:
conducting a thermal anneal operation on the substrate and the film stack while the substrate is directly supported on a pedestal heater, the thermal anneal operation comprising reducing one or more of a stress or a bow of the film stack; and
then conducting a radical treatment operation on the substrate and the film stack, the radical treatment operation comprising:
exposing the film stack to hydrogen radicals; and
removing contaminant particles from the film stack.
